(19) United States
(12) Patent Application Publication
(10) Pub. No.: US 2020/0241409 A1
(43) Pub. Date: Jul. 30, 2020

(54) Physical Vapor Deposition Target Assembly

(71) Applicant: Applied Materials, Inc., Santa Clara, CA (US)

(72) Inventors: Wen Xiao, Singapore (SG); Sanjay Bhat, Bangalore (IN); Shuwei Liu, Singapore (SG); Vibhu Jindal, San Jose, CA (US)

(73) Assignee: Applied Materials, Inc., Santa Clara, CA (US)

(21) Appl. No.: 16/750,586

(22) Filed: Jan. 23, 2020

Related U.S. Application Data
(60) Provisional application No. 62/796,777, filed on Jan. 25, 2019.

(51) Int. Cl. G03F 1/22; C23C 14/34; H01J 37/34

(52) U.S. Cl. CPC G03F 1/22; C23C 14/3407; H01J 37/3426; H01J 2237/332; H01J 37/3435; H01J 37/3417; C23C 14/3464

(57) ABSTRACT

Physical vapor deposition target assemblies, PVD chambers including target assemblies and methods of manufacturing EUV mask blanks using such target assemblies are disclosed. The target assembly includes a target shield adjacent the target and surrounding the peripheral edges of the target, the target shield comprising an insulating material and a non-insulating outer peripheral fixture to secure the target shield to the assembly.

### CROSS-REFERENCE TO RELATED APPLICATIONS

This application claims priority to U.S. Provisional Application No. 62/796,777, filed Jan. 25, 2019, the entire disclosure of which is hereby incorporated by reference herein.

### TECHNICAL FIELD

Embodiments of the present disclosure generally pertain to the field of physical vapor deposition. More specifically, embodiments of the disclosure relate to a physical vapor deposition target assembly, chambers including a physical vapor deposition target assembly and methods of manufacturing mask blanks using a physical vapor deposition target assembly.

### BACKGROUND

Sputtering is a physical vapor deposition (PVD) process in which high-energy ions impact and erode a solid target and deposit the target material on the surface of a substrate such as a semiconductor substrate or an ultra low expansion glass substrate. In semiconductor fabrication, the sputtering process is usually accomplished within a semiconductor process chamber also known as a PVD process chamber or a sputtering chamber.

A physical vapor deposition chamber is used to sputter deposit material onto a substrate to manufacture integrated circuit chips, displays or extreme ultraviolet (EUV) mask blanks. An EUV mask blank includes a multilayer stack, which is a structure that is reflective to extreme ultraviolet light. Typically, the physical vapor deposition chamber comprises an enclosure wall that encloses a process zone into which a process gas is introduced, a gas energizer to energize the process gas, and an exhaust port to exhaust and control the pressure of the process gas in the chamber. The chamber is used to sputter deposit a material from a physical vapor deposition target onto the substrate, such as a metal, for example, aluminum, copper, tungsten or tantalum; or a metal compound such as tantalum nitride, tungsten nitride or titanium nitride. In the physical vapor deposition processes, the physical vapor deposition target is bombarded by energetic ions, such as a plasma, causing material to be ejected from the target and deposited as a film on the substrate.

A typical physical vapor deposition chamber has a target assembly including disc-shaped target of solid metal or other material supported by a backing plate that holds the target. In physical vapor deposition chamber used in the manufacture of EUV mask blanks, every defect generated during multilayer deposition affects the product yield. In particular, small particles are the cause of “killer” defects of sub-micron to several microns during the manufacture of EUV mask blanks. A single “killer” defect falling on a mask blank will render the mask blank useless. Accordingly, there is a need to provide target assemblies that reduce the generation of particulates.

### SUMMARY

Accordingly, one or more embodiments of the disclosure are directed to a target assembly for use in a physical vapor deposition chamber the target assembly comprising a target backing plate; a target comprising peripheral edges and a front face defining a target surface extending between the peripheral edges, the target affixed to the target backing plate; a target shield adjacent the target and surrounding the peripheral edges of the target, the target shield comprising an insulating material, an outer periphery defining a target shield outer diameter and an inner peripheral surface adjacent the peripheral edges of the target; and a non-insulating outer peripheral fixture comprising an inner diameter, the outer peripheral fixture inner diameter less than the target shield outer diameter to secure the target shield so that the inner peripheral surface of the target shield is spaced apart from the peripheral edges of the target to provide a gap between the inner peripheral surface of the target shield and the peripheral edges of the target.

Another aspect of the disclosure pertains to physical vapor deposition apparatus comprising a chamber having a wall defining a process area including a substrate support; a target backing plate; a target comprising peripheral edges and a front face defining a target surface extending between the peripheral edges, the target affixed to the target backing plate; a power source coupled to the target to sputter material from the target; a target shield adjacent the target and surrounding the peripheral edges of the target, the target shield comprising an insulating material, an inner peripheral surface adjacent the peripheral edges of the target and an outer periphery defining a target shield outer diameter; and a non-insulating outer peripheral fixture comprising an inner diameter, the outer peripheral fixture inner diameter less than the target shield outer diameter to secure the target shield so that the inner peripheral surface of the target shield is spaced apart from the peripheral edges of the target to provide a gap between the inner peripheral surface of the target shield and the peripheral edges of the target.

Another aspect of the disclosure pertains to a method of manufacturing an extreme ultraviolet mask blank comprising depositing alternating layers of a first material and a second material reflective of extreme ultraviolet light from a first target and a second target, each of the first target and the second target comprising: a target backing plate; a target comprising peripheral edges and a front face defining a target surface extending between the peripheral edges, the target affixed to the target backing plate; a target shield adjacent the target and surrounding the peripheral edges of the target, the target shield comprising an insulating material and an outer periphery defining a target shield outer diameter; and a non-insulating outer peripheral fixture comprising an inner diameter, the outer peripheral fixture inner diameter less than the target shield outer diameter to secure the target shield so that the outer periphery of the target shield is spaced apart from the peripheral edges of the target to provide a gap between the outer periphery of the target shield and the peripheral edges of the target.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is an exploded isometric view of a physical vapor deposition target assembly according to an embodiment of the disclosure;

FIG. 2 is a top plan view of a physical vapor deposition target assembly according to an embodiment of the disclosure;

FIG. 3 is a cross-sectional view of a physical vapor deposition apparatus including a physical vapor deposition target according to an embodiment of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “horizontal” as used herein is defined as a plane parallel to the plane or surface of a mask blank, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures.

The term “on” indicates that there is direct contact between elements. The term “directly on” indicates that there is direct contact between elements with no intervening elements.

Those skilled in the art will understand that the use of ordinals such as “first” and “second” to describe process regions do not imply a specific location within the processing chamber, or order of exposure within the processing chamber.

According to an embodiment of the disclosure, a target assembly is provided that can better shield the target backing plate and reduces “killer” defects for EUV mask blank production.

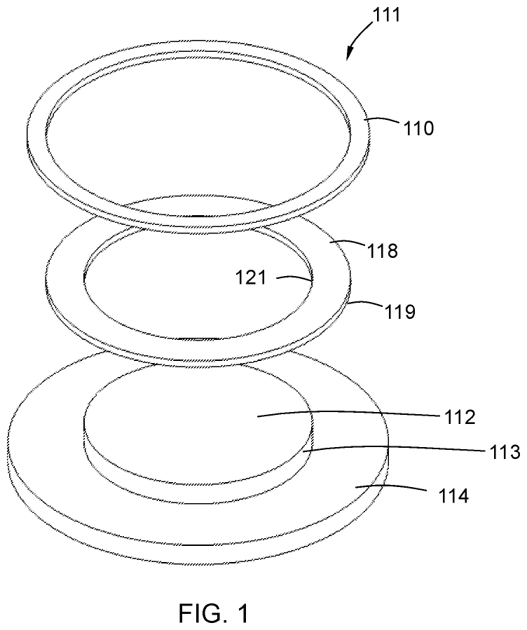

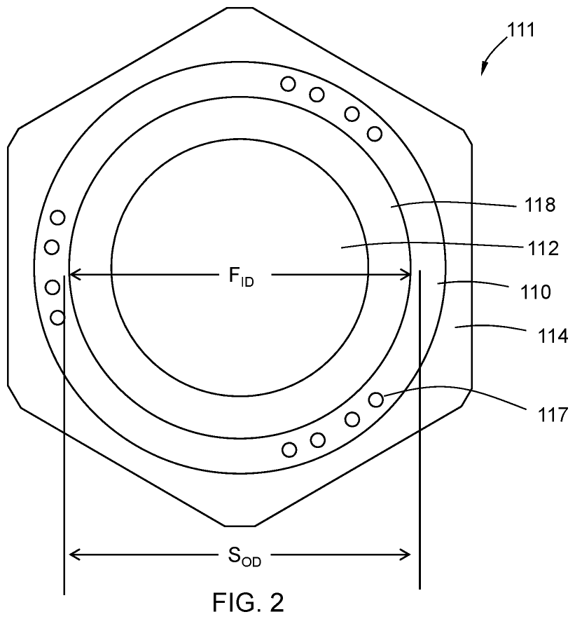

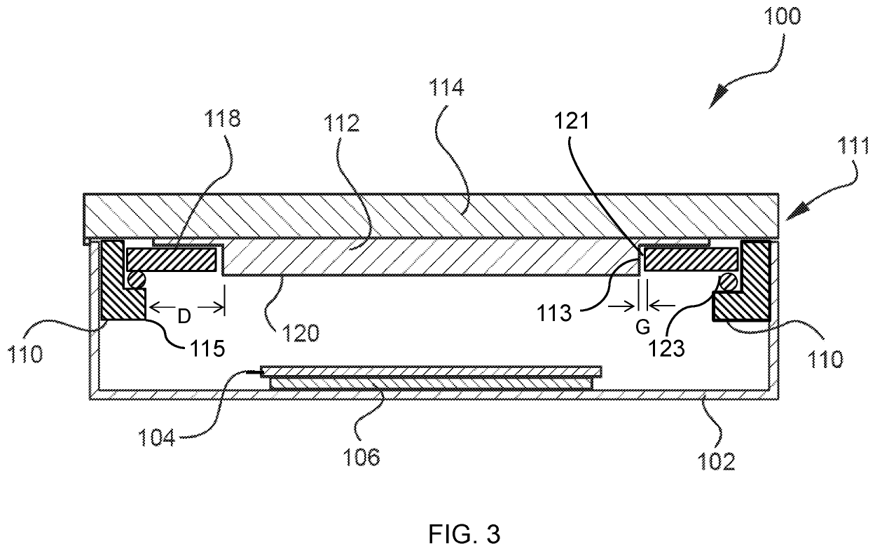

Referring now to FIGS. 1-3, the present disclosure pertains to target assembly 111 shown in FIGS. 1 and 2, which is used in a physical vapor deposition apparatus 100 such as a PVD chamber as shown in FIG. 3. In an embodiment, a target assembly 111 comprises a target backing plate 114, a target 112 comprising peripheral edges 113 and a front face 120 defining a target surface extending between the peripheral edges 113, the target affixed to the target backing plate 114. The target assembly 111 further comprises a target shield 118 adjacent the target 112 and surrounding the peripheral edges 113 of the target 112, the target shield 118 comprising an insulating material and an outer periphery 119 defining a target shield outer diameter S_{OD}. The target shield further comprise an inner peripheral surface 121 adjacent the peripheral edges 113 of the target 112. The target assembly 101 further comprises a non-insulating outer peripheral fixture 110 comprising an inner diameter, the outer peripheral fixture inner diameter F_{ID} is less than the target shield outer diameter S_{OD} to secure the target shield so that the inner peripheral surface 121 of the target shield 118 is spaced apart from the peripheral edges 113 of the target to provide a small gap G between the inner peripheral surface 121 of the target shield 118 and the peripheral edges 113 of the target 112. The small gap G reduces the chance for particles on the backing plate to flake into the chamber. Sputtering materials will not be re-deposited on the backing plate of target due to the small gap. In one or more embodiments, the gap G is in a range of 0.01 to 0.04 inches (0.0254 to 0.1016 cm).

FIG. 3 is a schematic, cross-sectional illustration of a physical vapor deposition apparatus 100 in the form of a physical vapor deposition chamber comprising a chamber body 102 and a substrate 104 supported by a substrate support 106 within the chamber body 102. The target assembly 111 includes the target 112 supported by the backing plate 114. The target includes a front face 120 or sputterable area disposed in a spaced relationship with respect to the substrate support 106. For the sake of ease of illustration, a shield comprising a generally annular shaped metal ring extends circumferentially around the target is not shown. The shield of some embodiments is held in place in the chamber by a shield support. The front face 120 of the target 112 is substantially flat.

The substrate support 106 may be electrically floating or may be biased by a pedestal power supply (not shown). In some embodiments, a process gas is introduced into the physical vapor deposition apparatus 100 via a gas delivery system that typically includes a process gas supply (not shown) including one or more gas sources that feed one or more gas conduits that allow gas to flow into the chamber via a gas inlet that is typically an opening in one of the walls of the chamber. The process gas may comprise a non-reactive gas, such as argon or xenon that energetically impinges upon and sputters material from a target 112. The process gas may also comprise a reactive gas, such as one or more of an oxygen-containing gas and a nitrogen-containing gas, that are capable of reacting with the sputtered material to form a layer on the substrate 104. The target 112 is electrically isolated from the physical vapor deposition apparatus 100 and is connected to a target power supply (not shown), for example, an RF power source, a DC power source, a pulsed DC power source, or a combined power source that uses RF power and/or DC power or pulsed DC power. In one embodiment, the target power source applies negative voltage to the target 112 energizing the process gas to sputter material from the target 112 and onto the substrate 104.

The sputtered material from the target, which is a non-insulator, and in some embodiments a metal such as molybdenum or a semiconductor such as silicon on the substrate 104 and forms a solid layer of material. The target assembly 111 includes the backing plate 114 that is joined to the target 112. The back face of the target opposite the front face 120 is joined to the backing plate. It will be appreciated that the target 112 is usually joined to the backing plate by welding, brazing, mechanical fasteners or other suitable joining techniques. The backing plate of some embodiments is fabricated from a high strength, electrically conductive metal in electrical contact with the target. The target backing plate 114 and target 112 may also be formed together as a unitary or integral structure, but typically, they are separate components joined together.

In one or more embodiments, the target shield 118 comprises an insulating material which comprises a ceramic material. In some embodiments, the ceramic material exhibits a volume resistivity greater than or equal to 10¹⁴ ohm-cm. Volume resistivity is a material property that can be utilized to calculate the electrical resistance of a material. For materials with high resistivity, a two-wire resistance test according to IPC-TM-650 may be used to measure the volume resistivity. In one or more embodiments, the target shield is a continuous piece of material that does not include any holes or openings, and the target shield 118 is not fastened to the backing plate 114 with screws or bolts.

In some embodiments, the ceramic material of the target shield 118 comprises aluminum oxide and exhibits a volume resistivity greater than or equal to 10¹⁴ ohm-cm. In some embodiments, the target assembly 111 further comprises an O-ring 123 disposed between the outer peripheral fixture 110 and the target shield 118. In some embodiments, the O-ring 123 comprises an elastomeric material such as Viton®. The O-ring provides a cushion between outer peripheral fixture 110 and the target shield 118. In some embodiments, the inner peripheral fixture 110 comprises a plurality of openings 117 sized to receive fasteners such as bolts or screws to secure the peripheral fixture 110 to the backing plate 114.

In one or more embodiments, the material of the target shield 118 has a sufficiently high electrical resistance to prevent electrical contact between the target and other grounded parts in the target assembly. In some embodiments, the backing plate 114 is cleaned, textured.

In one or more embodiments, the target 112 comprises a non-insulating material. In some embodiments, the target assembly comprises a metal or a metalloid. The metal in some embodiments comprises molybdenum or tantalum. In some embodiments, the metalloid comprises silicon. In some embodiments, the target comprises silicon or molybdenum.

According to some embodiments, the outer peripheral fixture inner diameter F_{ID} is dimensioned to provide a distance D between the target peripheral edge 113 and an inner edge 115 of the outer peripheral fixture 110 to prevent arcing between the outer peripheral fixture 110 and the target peripheral edge 113. In some embodiments, this distance D is greater than 1 inch (2.54 cm). In some embodiments, the physical vapor deposition apparatus comprises multiple target assemblies.

Another aspect of the disclosure pertains to a method of manufacturing an extreme ultraviolet mask blank. The method comprises depositing alternating layers of a first material and a second material reflective of extreme ultraviolet light from a first target assembly and a second target assembly, each of the first target assembly and the second target assembly comprising a target backing plate, a target comprising peripheral edges and a front face defining a target surface extending between the peripheral edges, the target affixed to the target backing plate. Each of the first target assembly and the second target assembly further comprises a target shield adjacent the target and surrounding the peripheral edges of the target, the target shield comprising an insulating material, inner peripheral surface and an outer periphery defining a target shield outer diameter and a non-insulating outer peripheral fixture comprising an inner diameter, the outer peripheral fixture inner diameter less than the target shield outer diameter to secure the target shield so that the inner peripheral surface of the target shield is spaced apart from the peripheral edges of the target to provide a gap between the inner peripheral surface of the target shield and the peripheral edges of the target.

The target assemblies and physical vapor deposition apparatus described herein according to one or more embodiments are utilized in the manufacture of EUV mask blanks formed on a substrate. The substrate is an element for providing structural support to the extreme ultraviolet reflective element. In one or more embodiments, the substrate is made from a material having a low coefficient of thermal expansion (CTE) to provide stability during temperature changes. In one or more embodiments, the substrate has properties such as stability against mechanical cycling, thermal cycling, crystal formation, or a combination thereof. The substrate according to one or more embodiments is formed from a material such as silicon, glass, oxides, ceramics, glass ceramics, or a combination thereof.

The multilayer stack is a structure that is reflective to the extreme ultraviolet light. The multilayer stack includes alternating reflective layers of a first reflective layer and a second reflective layer.

The first reflective layer and the second reflective layer form a reflective pair. In a non-limiting embodiment, the multilayer stack includes a range of 20-60 of the reflective pairs for a total of up to 120 reflective layers.

The first reflective layer and the second reflective layer are formed from a variety of materials. In an embodiment, the first reflective layer and the second reflective layer are formed from silicon and molybdenum, respectively. The first reflective layer and the second reflective layer have a variety of structures.

Because most materials absorb light at extreme ultraviolet wavelengths, the optical elements used are reflective instead of the transmissive as used in other lithography systems. The multilayer stack forms a reflective structure by having alternating thin layers of materials with different optical properties to create a Bragg reflector or mirror.

In an illustrative embodiment, the multilayer stack is formed using a physical vapor deposition technique, such as magnetron sputtering. In an embodiment, the first reflective layer and the second reflective layer of the multilayer stack have the characteristics of being formed by the magnetron sputtering technique including precise thickness, low roughness, and clean interfaces between the layers. In an embodiment, the first reflective layer and the second reflective layer of the multilayer stack have the characteristics of being formed by the physical vapor deposition including precise thickness, low roughness, and clean interfaces between the layers.

The physical dimensions of the layers of the multilayer stack formed using the physical vapor deposition technique is precisely controlled to increase reflectivity. In an embodiment, the first reflective layer, such as a layer of silicon, has a thickness of 4.1 nm. The second reflective layer, such as a layer of molybdenum, has a thickness of 2.8 nm. The thickness of the layers dictates the peak reflectivity wavelength of the extreme ultraviolet reflective element. If the thickness of the layers is incorrect, the reflectivity at the desired wavelength 13.5 nm is reduced.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A target assembly for use in a physical vapor deposition chamber the target assembly comprising:
a target backing plate;
a target comprising peripheral edges and a front face defining a target surface extending between the peripheral edges, the target affixed to the target backing plate;
a target shield adjacent the target and surrounding the peripheral edges of the target, the target shield comprising an insulating material, an outer periphery defining a target shield outer diameter and an inner peripheral surface adjacent the peripheral edges of the target; and
a non-insulating outer peripheral fixture comprising an inner diameter, the outer peripheral fixture inner diameter less than the target shield outer diameter to secure the target shield so that the inner peripheral surface of the target shield is spaced apart from the peripheral edges of the target to provide a gap between the inner peripheral surface of the target shield and the peripheral edges of the target.

2. The target assembly of claim 1, wherein the insulating material comprises a ceramic material.

3. The target assembly of claim 2, wherein the ceramic material exhibits a volume resistivity greater than or equal to 10¹⁴ ohm-cm.

4. The target assembly of claim 3, wherein the ceramic material comprises aluminum oxide.

5. The target assembly of claim 1, further comprising an O-ring disposed between the outer peripheral fixture and the target shield.

6. The target assembly of claim 5, wherein the target comprises a non-insulating material.

7. The target assembly of claim 6, wherein the target assembly comprises a metal or a metalloid.

8. The target assembly of claim 7, wherein the target comprises silicon or molybdenum.

9. The target assembly of claim 7, wherein the outer peripheral fixture inner diameter is dimensioned to provide a distance between the target peripheral edge and the outer peripheral fixture to prevent arcing between the outer peripheral fixture and the target peripheral edge.

10. A physical vapor deposition apparatus comprising:
a chamber having a wall defining a process area including a substrate support;
a target backing plate;
a target comprising peripheral edges and a front face defining a target surface extending between the peripheral edges, the target affixed to the target backing plate;
a power source coupled to the target to sputter material from the target;
a target shield adjacent the target and surrounding the peripheral edges of the target, the target shield comprising an insulating material, an inner peripheral surface adjacent the peripheral edges of the target and an outer periphery defining a target shield outer diameter; and
a non-insulating outer peripheral fixture comprising an inner diameter, the outer peripheral fixture inner diameter less than the target shield outer diameter to secure the target shield so that the inner peripheral surface of the target shield is spaced apart from the peripheral edges of the target to provide a gap between the inner peripheral surface of the target shield and the peripheral edges of the target.

11. The physical vapor deposition apparatus of claim 10, wherein the insulating material comprises a ceramic material.

12. The physical vapor deposition apparatus of claim 11, wherein the ceramic material exhibits a volume resistivity greater than or equal to 10¹⁴ ohm-cm.

13. The physical vapor deposition apparatus of claim 12, wherein the ceramic material comprises aluminum oxide.

14. The physical vapor deposition apparatus of claim 10, further comprising an O-ring disposed between the outer peripheral fixture and the target shield.

15. The physical vapor deposition apparatus of claim 14, wherein the target comprises a non-insulating material.

16. The physical vapor deposition apparatus of claim 15, wherein the target comprises a metal or a metalloid.

17. The physical vapor deposition apparatus of claim 16, wherein the target comprises silicon or molybdenum.

18. The physical vapor deposition apparatus of claim 16, wherein the outer peripheral fixture inner diameter is dimensioned to provide a distance between the target peripheral edge and the outer peripheral fixture to prevent arcing between the outer peripheral fixture and the target peripheral edge.

19. The physical vapor deposition apparatus of claim 10, wherein the apparatus comprises multiple target assemblies.

20. A method of manufacturing an extreme ultraviolet mask blank comprising:
depositing alternating layers of a first material and a second material reflective of extreme ultraviolet light from a first target and a second target, each of the first target and the second target comprising:
a target backing plate;
a target comprising peripheral edges and a front face defining a target surface extending between the peripheral edges, the target affixed to the target backing plate;
a target shield adjacent the target and surrounding the peripheral edges of the target, the target shield comprising an insulating material and an outer periphery defining a target shield outer diameter; and
a non-insulating outer peripheral fixture comprising an inner diameter, the outer peripheral fixture inner diameter less than the target shield outer diameter to secure the target shield so that the outer periphery of the target shield is spaced apart from the peripheral edges of the target to provide a gap between the outer periphery of the target shield and the peripheral edges of the target.
